(19) United States
(12) Patent Application Publication
(10) Pub. No.: US 2007/0158829 A1
(43) Pub. Date: Jul. 12, 2007

(54) Connecting module having passive components

(75) Inventors: Yuan-Chin Hsu, Yang-Mei (TW); Chen-Hsiung Yang, Yang-Mei (TW)

Correspondence Address: John Chen, Room 303, 3F., No 25, Sec. 1, Changan E. Road, Taipei, 10441, TW

(73) Assignee: Touch Micro-system Co., Ltd.

(21) Appl. No.: 11/434,733

(22) Filed: May 17, 2006

(30) Foreign Application Priority Data
Jan. 12, 2006 (TW) 095101211

(51) Int. Cl. H01L 23/52; H01L 23/34; H01L 21/00

(52) U.S. Cl. 257/724; 438/107; 257/924; 257/E23.057

(57) ABSTRACT

The present invention provides a connecting module having at least one passive component including a substrate, a connecting wire layout, at least one passive component and a chip-setting area, wherein the connecting wire layout is formed on the substrate, the passive components are formed on the connecting wire layout to electrically connect to the connecting wire layout. The chip-setting areas are formed in the substrate locating at different areas from the connecting wire layout, wherein the size of the passive components can be adjusted to match the needed impedance, and the numbers and the location of the chip-setting areas can be adjusted dynamically for reducing the dimension of the module.

### FIELD OF INVENTION

The invention relates to system with a multi-chip boarding package and a manufacturing method and structure of a connecting module, and more particularly to a method and structure for integrating the manufacturing process of the passive components and settling a chip by utilizing the space of the substrate to decrease the packaging difficulty.

### DESCRIPTION OF RELATED ARTS

Recently, the trend of the development of the electronic products is toward lightening, thinning, shortening, minifying, and high performance. And also the trend of the technology of the packaging market is toward high frequency, more I/O pins, and minification. With the progress of the IC manufacturing process, the sizes of the devices of an IC chip is getting smaller, the processing speed of data is getting faster, the required frequency is getting higher, and the requirement of the communication to the external for data is also getting more and more. In another word, the number of the pins of an IC chip is needed to be getting more and more. Therefore, the boarding package for providing high pins and high frequency becomes the main stream.

Now the boarding package is classified as mono-chip and multi-chip package by the number of the chips. The mono-chip package includes ball grid array (BGA), flip chip (FC), chip scale package (CSP), pin grid array package (PGA), and column grid array (CGAQ). The multi-chip package includes system on package (SOP), such as stack IC package, multi-chip module (MCM), and multi-chip package memory (MCP).

SOP refers to integrate at least two dies together by packaging. It is also called system-in-package (SiP). SOP can be classified as 3 main types, multi-chip package (MCP), multi-chip module (MCM), and integrated packaging (IP). MCP includes two main types, side-by-side, and stacked chip. The packaging methods and characteristics are described as the following:
1. referring to FIG. 1, it is the architecture of the side-by-side MCP 100. The cost of the side-by-side architecture 100 is lower. But because there is no connecting, the pins of the side-by-side architecture 100 are almost the same as the individual package.
2. referring to FIG. 2, it is the architecture of the stacked MCP 200. The required area of the stacked MCP can be reduced, but the manufacturing process of the stacked MCP needs to be more accurate.

Besides, SOP is involved in whether the devices can be integrated in the same manufacturing process when manufacturing the chip. And even the devices can be integrated in the same manufacturing process, there are some problems needed to be considered, such as if the performance of the chip is reduced, if the yield can be maintained, and how much the cost is increased. In addition, for the reason not to complicate the packaging process and not to increase the area, the number of the dies to be integrated is limited. The more dies are packaged together, the lower yield of packaging is achieved.

Therefore, the present invention provides a connecting module architecture with passive components and manufacturing process thereof to resolve the conventional packaging methods.

### SUMMARY OF THE PRESENT INVENTION

An object of the present invention is to provide a connecting module with passive components, comprising at least a device settling area and at least a passive component, wherein the size of the passive component can be adjusted to generate the required resistance of the connecting module. The connecting circuits, number and the layout of the device settling areas can be dynamically adjusted when needed to reduce the size of the module.

Another object of the present invention is to provide a connecting module with passive components, comprising at least a device settling area and at least a passive component, the thickness of the architecture film of the connecting module with passive components and size of the wires can be adjusted in the needs of the resistances of different components.

Another object of the present invention is to provide a connecting module with passive components, comprising at least a device settling area and at least a passive component, wherein the connecting circuits of the device settling areas are built in the electric connecting module to reduce the pin number of the package and to increase the reliability of the connecting module.

Another object of the present invention is to provide a connecting module with passive components, comprising at least a device settling area and at least a passive component, wherein the device settling areas are grooves, capable of being inserted at least a device not to increase the height of the electric connecting module after being inserted the device, to reduce the manufacturing difficulty when proceeding the stacked semiconductor manufacturing process.

Another object of the present invention is to provide a connecting module with passive components in wafer class packaging manufacturing process, comprising at least a device settling area and at least a passive component, wherein the connecting module can be segmented after being packaged and tested.

Another object of the present invention is to provide a semiconductor manufacturing process to form a connecting module with passive components, wherein the surface of the connecting module with passive components employs the photo sensitive material with the electric isolating ability to protect the module and define at least a device settling area.

Another object of the present invention is to provide a chip module with passive components, comprising at least a device settling area, at least a passive component, and at least a chip, wherein the sizes of the passive components can be adjusted to generate the required resistances of the connecting module, the connecting circuits, number, and the layout of the device settling area can be dynamically adjusted in need to reduce the size of the module, and the chips are settled in the device settling areas to increase the reliability of the semiconductor module.

Accordingly, in order to accomplish the one or some or all above objects, the present invention provides a connecting module with passive components, comprising:

a substrate;

a connecting wire layout, comprising at least a connecting wire formed on the substrate to provide the required electric connecting for operating the chip module;

a passive component layout, comprising at least a passive component formed on the connecting wire layout and connected to the connecting wire layout to provide the required resistances for operating the chip module;

at least a chip-setting area, the chip-setting areas are formed by etch the substrate and locating in the different area from the connecting wire layout and the passive component layout; and

at least a chip, settled in the chip-setting area and connected to the connecting wire layout.

Accordingly, in order to accomplish the one or some or all above objects, the present invention provides a semiconductor manufacturing process to form the chip module with passive components, comprising the following steps:
(a) forming a connecting wire layout on a substrate, wherein the connecting wire layout comprises at least a connecting wire to provide the required electric connecting for operating the chip module;
(b) forming a passive component layout on the connecting wire layout, wherein the passive component layout comprises at least a passive component, electrically connected to the connecting wire layout, to provide the required resistances for operating the chip module;
(c) etching the substrate to generate a chip-setting layout, wherein the chip-setting layout comprises at least a chip-setting groove locating at the different area from the connecting wire layout on the substrate;
(d) settling at least a chip from the external in the chip-setting groove;
(e) electrically connecting the chip from the external and the connecting wire layout.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

FIG. 1 illustrates the side-by-side multi-chip packaging structure.

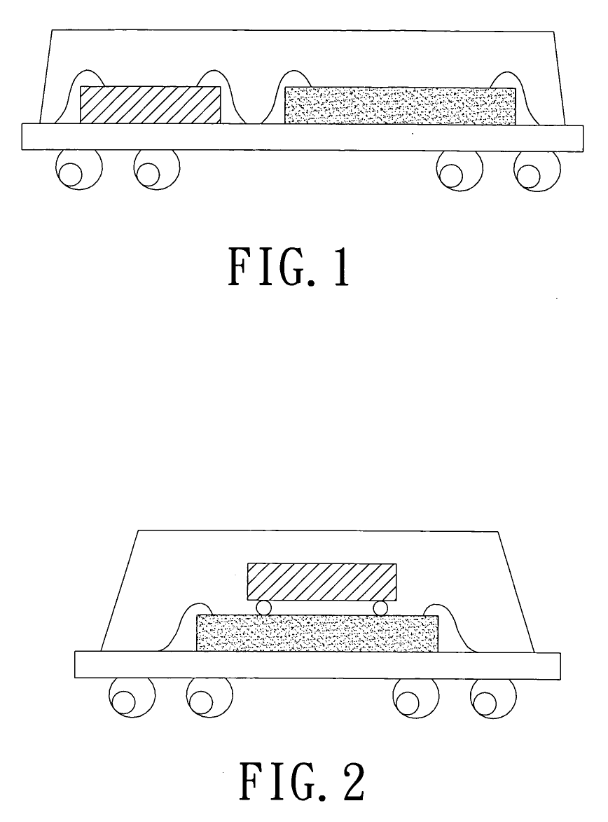

FIG. 2 illustrates the stacked multi-chip packaging structure.

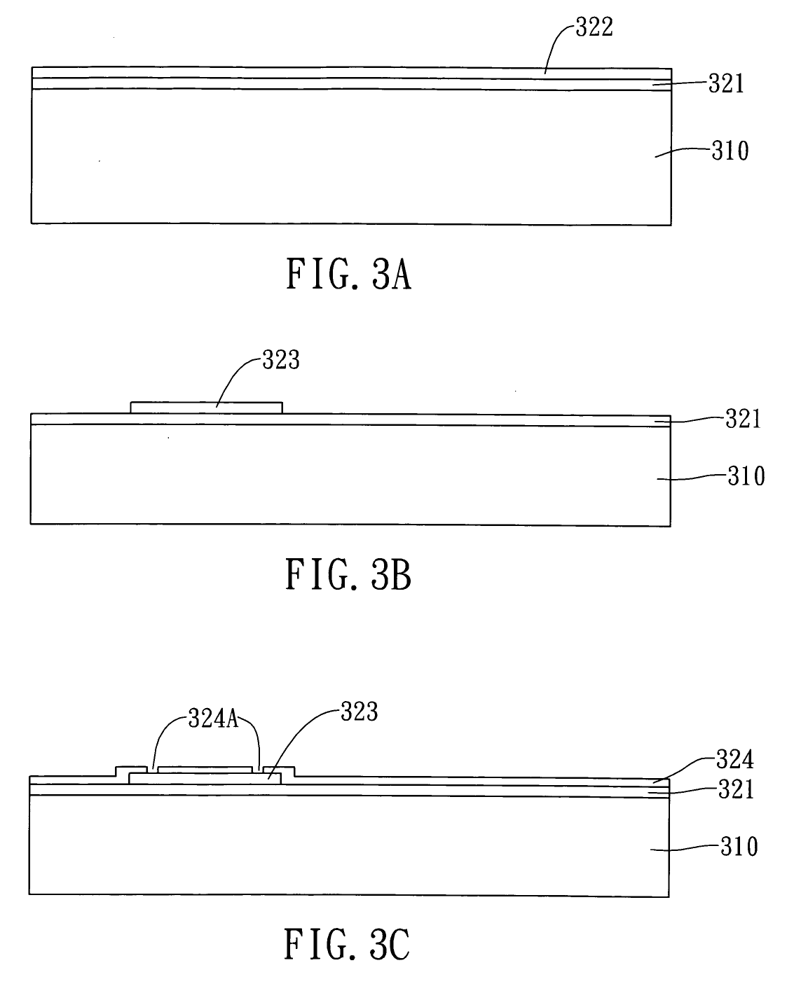

FIG. 3A-3E illustrate the manufacturing process of the connecting wire layout in accordance with the present invention.

FIG. 3F-3H illustrate the manufacturing process of the passive component in accordance with the present invention.

FIG. 3I-3K illustrate the manufacturing process of the chip-setting area in accordance with the present invention.

### DETAILED DESCRIPTION OF THE PREFERRED EMBODIMENT

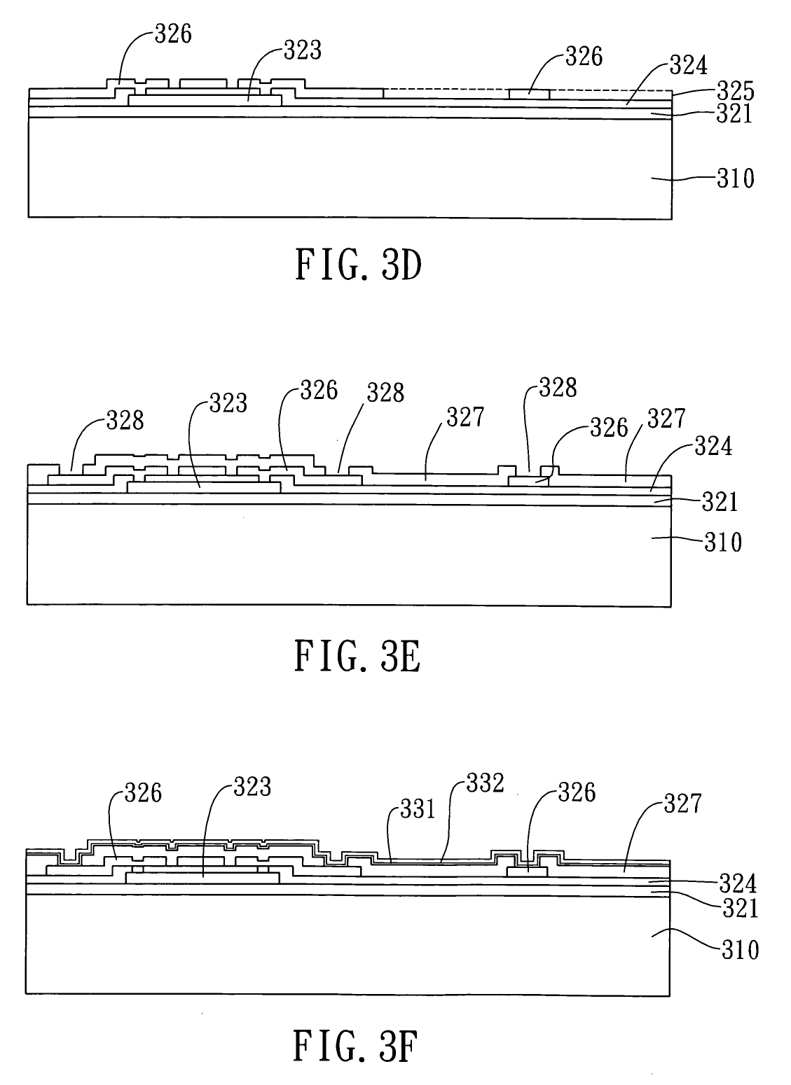

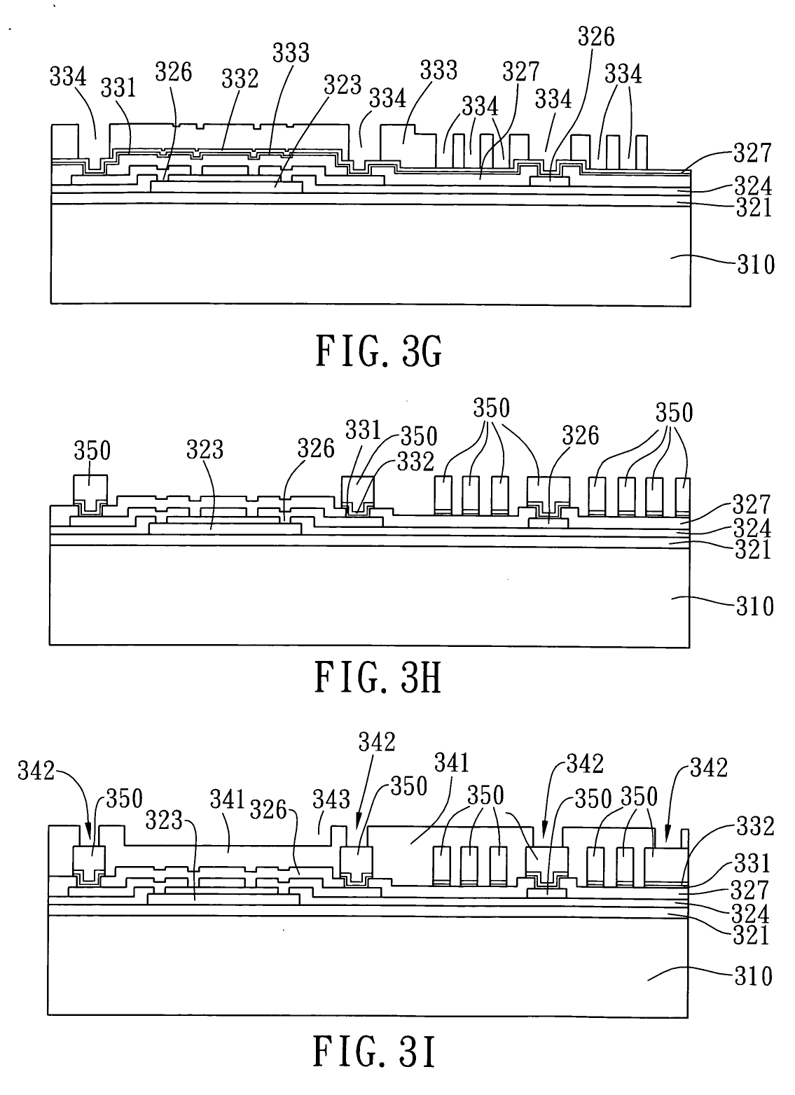

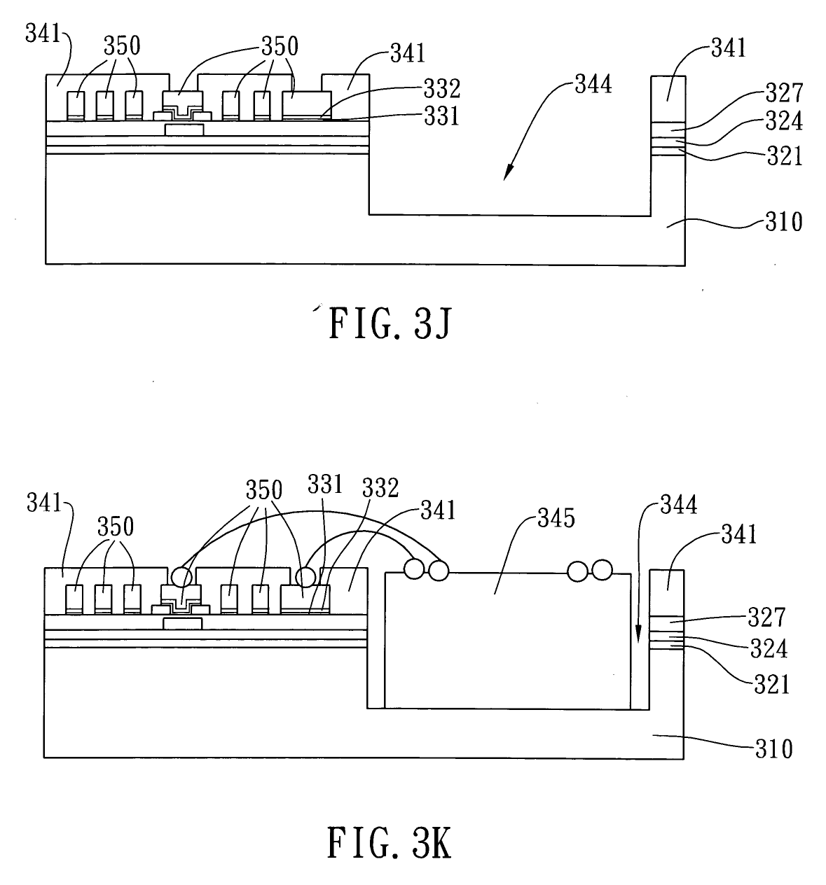

Referring to the FIG. 3, it is a semiconductor manufacturing process disclosed by the preferred embodiment of the present invention to form a connecting module with passive components. In the embodiment, a connecting wire layout is formed on a wafer first.

Referring to FIG. 3A-3E, they are the manufacturing process of the connecting wire layout in accordance with the preferred embodiment of the present invention. Referring to FIG. 3A, the first silicon dioxide layer 321 is formed on a wafer 310 first, and then an aluminum-copper alloy layer 322 is deposited on the silicon dioxide layer 321. In the embodiment, the first silicon dioxide layer 321 is formed in the thermal diffusion method, and the aluminum-copper alloy layer 322 is formed in the physics deposition method, but not restricted.

Referring to FIG. 3B, the aluminum-copper alloy layer 322 is etched to form the first wiring layout 323 next. In the embodiment, the etching process defines the wiring for the aluminum-copper alloy layer 322 by exposing and developing, then the area not to be defined as the wiring in the aluminum-copper alloy layer 322 is etched to form the first wiring layout 323, and the photo sensitive material is removed last.

Referring to FIG. 3C, the second silicon dioxide layer 324 is formed on the first wiring layout, the first electric connecting opening layout 324A is defined on the second silicon dioxide layer 324 by exposing and developing next, and the second silicon dioxide layer 324 is etched to be defined as the connecting opening to expose the area which is for electric connecting in the first wiring layout 323. At last, the photo sensitive material is removed. The first wiring layout 323 exposed out of the first electric connecting opening layout 324A is the electric connecting nodes of the first wiring layout 323, and is the contact area as the electric connecting for the first wiring layout 323.

Referring to FIG. 3D, the second aluminum-copper alloy layer 325 is deposited on the second silicon dioxide layer 324 and connected to the first wiring layout 323 via the electric connecting opening layout to achieve the electric connecting with the first wiring layout 323. Next, the second aluminum-copper alloy layer 325 is etched to form the second wiring layout 326. In the embodiment, the second aluminum-copper alloy layer 325 is defined for the wiring by exposing and developing in the etching process, and then the area not to be defined as the wiring in the second aluminum-copper alloy layer 325 is etched to form the second wiring layout 326. At last, the photo sensitive material is removed.

Referring to FIG. 3E, the third silicon dioxide layer 327 is formed on the second wiring layout 326. Next, the second connecting opening layout 328 is defined on the third silicon dioxide 327 by exposing and developing, and the area defined as the opening in the third silicon dioxide layer 327 is etched to expose the area for electric connecting in the second wiring layout 326. At last, the photo sensitive material is removed. The second wiring layout 326 exposed out of the second connecting opening layout 328 is the electric connecting nodes of the second wiring layout 326.

The manufacturing process is employed in forming a connecting wire layout on a specific substrate, wherein there are two connecting wire layers in the connecting wire layout, but not restricted. The required number of the layers, materials, and manufacturing methods for achieving the wire connecting layout of the module are intended to be disclosed by the present invention.

Referring to FIG. 3F-3H, they are the manufacturing process of passive components in accordance with the preferred embodiment of the present invention. Referring to FIG. 3F, a barrier layer 331 and a seed layer 332 the third silicon dioxide layer 327 are formed on the third silicon dioxide layer 327 in order, wherein the barrier layer 331 is connected to the second wiring layout 326 via the second connecting opening layout 328, and the seed layer 332 is formed on the barrier layer 331.

The barrier layer 331 is the buffering layer between the second aluminum-copper alloy layer 325 and the seed layer 332. By employing the barrier layer 331, the problem due to the high diffusion coefficient of the copper and the electricity degeneration of the device when forming deep energy levels in the silicon substrate can be resolved, even the problem of the low adherent ability for the copper to the dielectrics. The conventional material employed in the barrier layer 331 is tungsten (W), titanium-tungsten (TiW), Ta/TaN, Ti/TiN, or the combination thereof, but not restricted. The seed layer 332 provides the required seed for forming the metal layer and avoid the peeling problem due to the large stress. The employed material in the seed layer 332 depends on the metal layer. The conventional material is copper or gold, but not restricted.

Referring to 3G, the first photo resist layer 333 is form on the seed layer 332. The material of the first photo resist layer 333 is the photo sensitive material capable of defining patterns by exposing and developing. In the embodiment, the first photo resist layer 333 comprises photosensitive BCB, and polyimide, but not restricted. The epoxy and UV glue are also the conventional gluing material. And the processing the exposing and developing, the passive component connecting opening layout 334 is defined on the first photo resist layer 333, and the area defined as the passive component connecting opening in the first photo resist layer 333 is etched. The seed layer 332 exposed out of the passive component connecting opening layout 334 are the electric connecting nodes of the seed layer 332, and are the contact area for electric connecting for the seed layer 332.

Referring to 3H, at least a passive component 350 is formed by electro-plating copper in the area of the seed layer 332 exposed out of the passive component connecting opening layout 334, such as the inductor, resistor, capacitor, and so on. The characteristics of the passive component can be controlled by the size of the opening of the connecting opening layout, shape, thickness, and the state of the surface.

Next, the first photo resist layer 333 is removed by the photo resistance remover, and the passive component, the seed layer 332, and the barrier layer 331 are etched separately to have the size of the passive component matches the required resistance. The area of the seed layer 332 not to be covered by the passive component and the barrier layer 331 are removed to expose the third silicon dioxide layer 327 out.

The mentioned manufacturing process is employed to form at least a passive component in the connecting wire layout. Any implementation of the modified order of the manufacturing process, etching method, and manufacturing materials in accordance with the mentioned above is intended to be disclosed by the present invention.

Referring to FIG. 31-3K, they are the manufacturing process of the chip-setting in accordance with the preferred embodiment of the present invention. Referring to FIG. 31, the second photo resist layer 341 is coated by spin-coating first. Next, a connecting pad opening layout 342 and a chip-setting opening layout 343 are defined on the second photo resist layer 341, the areas defined as the connecting pad opening and chip-setting opening in the second photo resist layer 341 are etched, and the second photo resist layer 341 is processed by curing so that the second photo resist layer 341 can achieve the result of protecting the connecting module.

Referring to FIG. 3J, And then the second photo resist layer 341 is etched to expose the area, for electric connecting, of the passive component 350, and also the connection structure is etched by the active plasma etching apparatus to form at least a chip-setting area 344.

Referring to FIG. 3K, at least a chip is placed in the chip 345 settling area 344. In the embodiment, resin is employed to glue the chip 345 in the bottom of the chip-setting area 344. Next, the chip 345 is electrically connected to the electric connecting area of the specific passive component by wire bonding, but not restricted. Any method suitable for electrically connecting the chip 345 and the passive component can be alternate to implement.

The present invention is the manufacturing process for manufacturing a connecting module employing the wafer packaging structure instead of the electric connecting function of a part of the printed circuit board by integrating the passive component, connecting wire layout, and the chip-setting area to produce a connecting module. First, the required time and complexity of the manufacturing process are reduced by integrating the wafer packaging and manufacturing process of the passive component. In the meanwhile, the yields of the wafer and the passive components are increased by reducing the packaging time, signal degeneration of the external passive components, and indifferent effect to the system caused by the noise, and also by employing of the passivation layer. When the defects are generated in the manufacturing process, it is easy to recover. The chip-setting area is generated in the wafer itself so that the thickness of the connecting structure that the wafer is included is more uniform. The thickness of the packaging structure is not uniform due to the height of the chip to increase the complexity of the following stacked type manufacturing process. The reduction of the reliability caused by the complicate wiring between the passive components and the chip can be decreased by integrating the passive components with the chip. Also the cured photo resist layer is employed to increase the strength of the packaging structure.

One skilled in the art will understand that the embodiment of the present invention as shown in the drawings and described above is exemplary only and not intended to be limiting.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A chip module with passive components, comprising:
a substrate;
a connecting wire layout, comprising at least a connecting wire formed on the substrate to provide electric connecting for operating the chip module;
a passive component layout, comprising at least a passive component formed on the connecting wire layout, and connected to the connecting wire layout to provide a resistance for operating the chip module;
at least a chip-setting area, formed by etch the substrate, and locating at a different area from the connecting wire layout and the passive component layout; and
at least a chip, placed in the chip-setting area and connected to the connecting wire layout.

2. The chip module with passive components according to the claim 1, further comprising a barrier layer and a seed layer, wherein the barrier layer is connected to the connecting wire layout, and the seed layer is formed on the barrier layer and connected to the passive component layout.

3. The chip module with passive components according to the claim 2, further comprising a passivation layer covering the passive component layout and the connecting wire layout to increase reliability of the chip module.

4. The chip module with passive components according to the claim 1, wherein the passive component is controlled by a size, a shape, a thickness, or a state of a surface of the passive component.

5. The chip module with passive components according to the claim 1, wherein the connecting wire is controlled by a width of the connecting wire, or a thickness of a structure layer.

6. The chip module with passive components according to the claim 4, wherein the connecting wire is controlled by a width of the connecting wire, or a thickness of a structure layer.

7. The chip module with passive components according to the claim 3, wherein the passive component is controlled by a size, a shape, a thickness, or a state of a surface of the passive component.

8. The chip module with passive components according to the claim 6, wherein the connecting wire is controlled by a width of the connecting wire, or a thickness of a structure layer.

9. The chip module with passive components according to the claim 3, wherein the passivation layer comprises a photosensitive BCB, polyimide, epoxy or UV glue.

10. The chip module with passive components according to the claim 1, wherein location and quantity of the passive component and the chip-setting area depends on requirement of design.

11. A connecting module with passive components, comprising:
a substrate;
a connecting wire layout, comprising at least a connecting wire formed on the substrate to provide electric connecting for operating the chip module;
a passive component layout, comprising at least a passive component formed on the connecting wire layout, and connected to the connecting wire layout to provide a resistance for operating the chip module; and
at least a chip-setting area, formed by etch the substrate, and locating at a different area from the connecting wire layout and the passive component layout.

12. The connecting module with passive components according to the claim 11, further comprising a barrier layer and a seed layer, wherein the barrier layer is connected to the connecting wire layout, and the seed layer is formed on the barrier layer and connected to the passive component layout.

13. The connecting module with passive components according to the claim 12, further comprising a passivation layer covering the passive component layout and the connecting wire layout to increase reliability of the chip module.

14. The connecting module with passive components according to the claim 11, wherein the passive component is controlled by a size, a shape, a thickness, or a state of a surface of the passive component.

15. The connecting module with passive components according to the claim 11, wherein the connecting wire is controlled by a width of the connecting wire, or a thickness of a structure layer.

16. The connecting module with passive components according to the claim 14, wherein the connecting wire is controlled by a width of the connecting wire, or a thickness of a structure layer.

17. The connecting module with passive components according to the claim 13, wherein the passive component is controlled by a size, a shape, a thickness, or a state of a surface of the passive component.

18. The connecting module with passive components according to the claim 16, wherein the connecting wire is controlled by a width of the connecting wire, or a thickness of a structure layer.

19. The connecting module with passive components according to the claim 13, wherein the passivation layer comprises a photosensitive BCB, polyimide, epoxy or UV glue.

20. The connecting module with passive components according to the claim 11, wherein location and quantity of the passive component and the chip-setting area depends on requirement of design.

21. The connecting module with passive components according to the claim 18, wherein the substrate comprises a silicon wafer.

22. A semiconductor manufacturing process to form a chip module with passive components, comprising steps as the following:
(a) forming a connecting wire layout on a substrate, wherein the connecting wire layout comprises at least a connecting wire to provide a electric connecting for operating the chip module;
(b) forming a passive component layout on the connecting wire layout, wherein the passive component layout comprises at least a passive component, connected to the connecting wire layout, to provide a resistance for operating the chip module;
(c) etching the substrate to generate a chip-setting layout, wherein the chip-setting layout comprises at least a chip-setting area locating at a different area from the connecting wire layout on the substrate;
(d) placing at least a chip in the chip-setting area; and
(e) electrically connecting the chip and the connecting wire layout.

23. The semiconductor manufacturing process to form a chip module with passive components according to the claim 22, wherein the step (a) further comprises:
forming a barrier layer on the connecting wire layout, wherein the barrier layer is electrically connected to the connecting wire layout; and
forming a seed layer on the barrier layer, wherein the seed layer is electrically connected to the barrier layer.

24. The semiconductor manufacturing process to form a chip module with passive components according to the claim 22, wherein the step (e) further comprises:
forming a passivation layer on the connecting wire layout and the passive component layout to increase the reliability of the chip module.

25. The semiconductor manufacturing process to form a chip module with passive components according to the claim 23, wherein the step (e) further comprises:
forming a passivation layer on the connecting wire layout and the passive component layout to increase the reliability of the chip module.

26. The semiconductor manufacturing process to form a chip module with passive components according to the claim 22, wherein the passivation layer comprises a photosensitive BCB, polyimide, epoxy or UV glue.

27. The semiconductor manufacturing process to form a chip module with passive components according to the claim 25, wherein the passivation layer comprises a photosensitive BCB, polyimide, epoxy or UV glue.

28. The connecting module with passive components according to the claim 22, wherein location and quantity of the passive component and the chip-setting area depends on requirement of design.
